(19) United States
(12) Patent Application Publication
(10) Pub. No.: US 2007/0211517 A1
(43) Pub. Date: Sep. 13, 2007

(54) System and method for operating a memory circuit

(75) Inventor: James D. Burnett, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 11/373,584

(22) Filed: Mar. 10, 2006

(51) Int. Cl. G11C 11/00; G11C 11/34

(52) U.S. Cl. 365/154; 365/177

(57) ABSTRACT

A first gate of a multi-gate transistor within a pass gate can be provided with a bias voltage to alter the bias point of the multi-gate transistor. The bias point can be controlled differently during different phases of memory cell operation and the bias point can provide operational improvements during each phase of memory cell operation. In a specific configuration the multi-gate semiconductor device has a first current electrode connected to a first node of a bit cell, a second current electrode connected to a bit line, and a second gate electrode connected to a read/write line, wherein the control module can alter the bias point of the multi-gate semiconductor differently during different phases of memory cell operation. In one embodiment a FinFET can be connected in a parallel configuration with the multi-gate transistor.

### CROSS REFERENCE TO RELATED APPLICATIONS

The present application is related to co-pending U.S. patent application Ser. No. ______ (Client Reference No.: SC14541TP) entitled “SWITCH DEVICE AND METHOD,” filed on even date herewith and having at least one inventor in common.

### FIELD OF THE DISCLOSURE

The disclosure relates generally to electronic devices and more specifically to electronic devices having memory and methods for controlling such devices.

### BACKGROUND

In an effort to reduce the size of mobile electronic devices and increase the battery life of such devices, an emphasis has been placed on implementing low voltage circuit designs. However, designers of low voltage, nano-scale circuits face many challenges. One such challenge includes the design of reliable low voltage memory circuits. In particular, static random access memory (SRAM) cells can suffer performance degradation at low supply voltages. A typical SRAM memory can have millions of bit cells wherein each bit cell stores one bit of data. At low supply voltages, conventional memory systems cannot always reliably read, write, and retain data.

Operation of a SRAM is influenced by many factors. Specifically, when integrated circuits are manufactured, small variations in doping, layer thicknesses, and other procedures manifest as imprecise threshold voltages, leakage currents, and junction mismatches. These variations can effect operation of a SRAM. The ability of a memory to read and write data is measured in terms of static noise margin (SNM), write margin (WM), and cell current (Icell). The SNM of a SRAM memory cell is generally defined as the minimum noise voltage that, when present at a bit cell storage node, will make a bit cell flip to a wrong state. A bit cell is most vulnerable to noise during a read phase, during which, if a cell changes state a destructive read is said to occur. Cell current is the amount of current the memory cell can source or sink during a read phase. Wherein, write margin can be defined as a minimum voltage required on a bit line to pull a storage node low and flip the state of the bit cell from a high state to a low state during a write phase. A low write margin can lead to unsuccessful writes because it indicates that it is difficult to get data lines to drop to near zero volts. It is well known that design changes that improve one characteristic nearly always degrade at least one of the other characteristics, often to unacceptable levels. Accordingly, there is a need for a SRAM memory cell configuration that can overcome these problems

### BRIEF DESCRIPTION OF THE DRAWINGS

The present disclosure may be better understood, and its numerous features and advantages made apparent to those skilled in the art by referencing the accompanying drawing, in which like reference numbers indicate similar or identical items.

FIG. 1 is a block diagram of a memory cell configuration in accordance with a specific embodiment of the present disclosure;

FIG. 2 is a graph illustrating memory cell control signal configurations that can be utilized to control the operation of a memory cell;

FIG. 3 is a block diagram of an exemplary 6T memory cell configuration having independent bias inputs in accordance with one embodiment of the present disclosure;

FIG. 4 is a block diagram of another exemplary 6T memory cell configuration having independent bias inputs in accordance with another embodiment of the present disclosure;

FIG. 5 is a block diagram of an exemplary 4T memory cell configuration having independent bias inputs in accordance with yet another embodiment of the present disclosure;

FIG. 6 is a flow diagram of an exemplary method for operating a memory cell in accordance with a particular embodiment of the present disclosure;

FIG. 7 is another flow diagram of an exemplary method for operating a memory cell in accordance with a particular embodiment of the present disclosure;

FIG. 8 is a block diagram illustrating a control module of a device in greater detail.

FIG. 9 is a diagram illustrating a 3-dimensional rendition of a FinFET transistor in accordance with a specific embodiment; and

FIG. 10 is a diagram illustrating a cross-sectional view of a FinFET transistor having multiple gates in accordance with a specific embodiment.

### DETAILED DESCRIPTION

Pass gates in memory systems act as switches between data transmission lines, i.e., bit lines, and bit cells that store data. Memory systems rely on efficient pass gate operation to ensure robust memory system operation. For example, pass gates must provide a low impedance path when the pass gate is turned on during a read or a write phase and a high impedance path when the pass gate is turned off. Additionally, if a storage node of the bit cell is at a low voltage state, e.g., near zero volts, the pass gate should have minimal leakage currents when the bit line is at a high voltage state such that undesirable leakage currents do not flip the low voltage state of the cell to a high voltage state. Further, in certain bit cell configurations, such as a four transistor (4T) configuration, when the storage node is at a high voltage state, a pass gate should provide enough leakage current to assist in maintaining the high voltage state, but not so much as to cause undesirable power dissipation. All of these characteristics are difficult to achieve with traditional memory cell designs in scaled bit cells because of the limited features of pass gates that can be controlled in such traditional designs. In accordance with an embodiment of the present disclosure, a gate of a multi-gate transistor within a pass gate can be controlled independently from a gate controlled by the typical primary logic control signal, i.e., R/W signal, to bias the pass gate differently during different operational phases of memory cell operation.

In a particular embodiment, the multi-gate semiconductor device has a first current electrode (i.e., source/drain electrode) connected to a first node of a bit cell, a second current electrode connected to a bit line, a first gate electrode connected to a read/write line and a second gate electrode connected to control module. The control module can provide a control signal to the second gate electrode to alter the bias point of the multi-gate semiconductor device relative to a signal at the read/write line. Altering the bias point of the multi-gate semiconductor device can improve performance parameters during different phases of memory cell operation. For example, a first bias voltage can provide a first bias point for the multi-gate transistor during a write phase, a second bias voltage can provide a second bias point for the multi-gate transistor during a data retention phase, a third bias voltage can provide a third bias point for the multi-gate transistor during a stand-by or idle phase, and a fourth bias voltage can provide a fourth bias point for the multi-gate transistor during a read phase without adversely affecting the other operational phases. In this manner, performance of the memory cell can be enhanced during each phase. In one embodiment, after operational characteristics of a memory are determined, the deficiencies of the memory can be identified and the bias signals can be defined for each operational phase of the memory to improve specific memory characteristics during specific phases of memory operation.

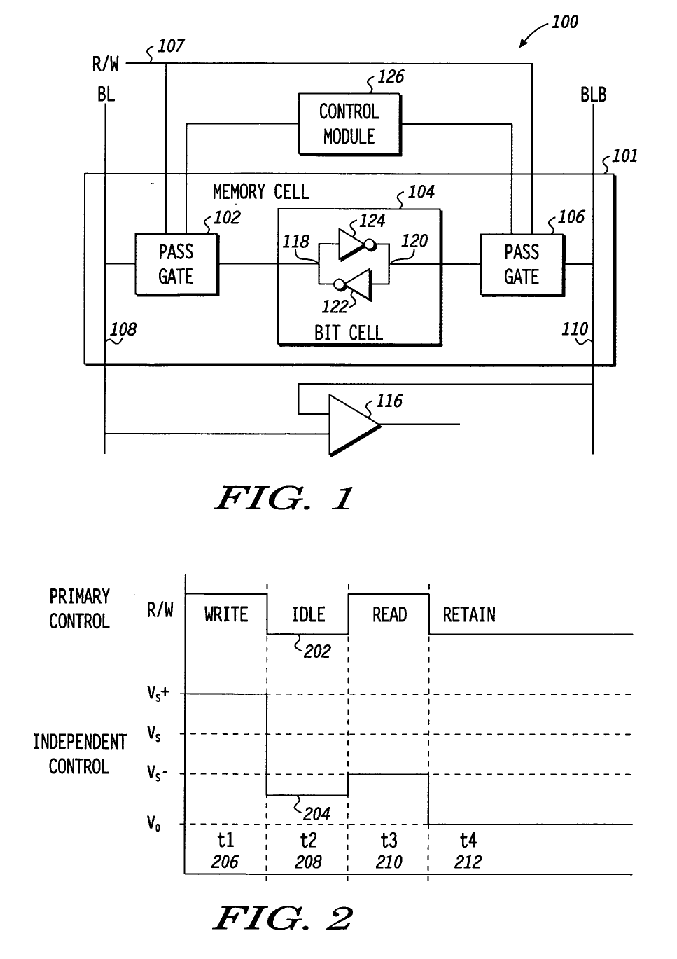

Referring to FIG. 1 an exemplary block diagram of a memory sub-system 100 is illustrated. In accordance with the illustrated embodiment, a bit cell 104 is connected to bit line BL 108 via a tunable pass gate TPG 102 and connected to bit line bar BLB 110 via tunable pass gate TPG 106. In operation, when an asserted write control signal is provided via read/write line R/W 107 to TPG 102 and TPG 106, TPG 102 and TPG 106 can turn on such that the logic signals at BL 108 and BLB 110 are provided to, and stored by, bit cell 104 during a write phase. During a read operation, the logic state of bit cell 104 can be detected or provided from the bit cell 104 to BL 108 and BLB 110 during a read phase. Therefore, TPG 102 and TPG 106 can act as switches to pass a current between the bit cell 104 and BL 108 and BLB 110 during a read phase and a write phase. In an embodiment, a sense circuit 116 can be connected to BL 108 and BLB 110 to read a value at storage nodes 118 and 120 of the bit cell 104 when TPG 102 and TPG 106 electrically connect first storage node 118 to BL 108 and second storage node 120 to BLB 110.

Bit cell 104 can function generally as two cross-coupled inverters. Specifically, an inverter 122 can have its output connected to the input of inverter 124 and its input connected to the output of inverter 124, wherein a signal provided to the input of one of the inverters can flip the state of both inverters to store a value of the signal. In this configuration, when storage node 118 is at a high voltage state, storage node 120 is at a low voltage state such that a differential signal can be provided to BL 108 and BLB 110 during a read phase.

TPG 102 and TPG 106 can include a multi-gate transistor or transistors such as a multi-gate fin-type field effect transistor (FinFET) or other multi-independent gate field effect transistors (MIGFETs), or switching devices that have a first control input to receive a traditional read/write control signal and a second control input to receive a bias signal to bias the operation of the switching device relative to the signal at the first gate input. The use of multi-gate transistors allows TPG 102 and TPG 106 to be biased differently during each operational phase to improve the operational characteristics of the memory cell. For example, a first bias voltage can be provided by independent control module 126 during a read phase, a second bias voltage can be provided during a write phase, a third bias voltage can be provided during an idle phase, and a fourth bias voltage can be provided during a retain or retention phase.

The voltage level of the bias signal may be different for a particular phase depending upon a desired characteristic. For example, during a read phase if an improved static noise margin is desired then the bias voltage may be lowered below the supply voltage, while if static noise margin is acceptable but a greater cell current is desired during the read phase then a higher bias voltage may be appropriate.

Control module 126 can provide a bias signal having such different bias voltages based upon the desired operational parameters TPG 102 and TPG 106. These different bias voltages can control a fractional amount of the channel region of transistors forming TPG 102 and TPG 106. Further, the different bias voltages can be based on the configuration and type of technology utilized in the pass gate design. Additionally, the bias voltage can be altered in real time responsive to environmental or temperature changes, or to compensate for process variations. In one embodiment, the bias voltage is provided to the bit cells utilizing conductors that run in parallel to bit lines within the integrated circuit such that particular columns, i.e., bit cells connected to a common bit lines, can receive the same bias signal.

Referring to FIG. 2, a timing diagram for an exemplary primary control signal, i.e., R/W signal, and an independent control signal, i.e., the bias signal, are illustrated in accordance with a particular embodiment of the present disclosure. It will be appreciated that for simplicity and clarity of illustration, the waveforms illustrated in FIG. 2 have not necessarily been drawn to scale and the timing relationships are merely exemplary. For example, the magnitude or size of the independent control signal waveform and the delays of some of the waveform transitions may be exaggerated relative to other waveform attributes. Additionally, rising and falling edges of the waveforms are drawn as idealized to assist in describing one embodiment, and in actuality these waveforms would typically have edges with measurable slope or slew rate

During memory cell operation, a read/write control signal, referred to herein as a primary control signal 202, can be provided to a first gate of a multi-gate transistor in a pass gate of a memory cell. Concurrently, and based on the operational phase of memory cell operation (i.e. a read, write, idle or retain phase) and memory cell performance deficiencies, a control signal 204 can be provided to a second gate of the multi-gate transistor to adjust the bias point of the transistor or transistors in the pass gate. As will be described below, the pass gate may include a single multi-independent gate field effect transistor (MIGFET), such as a multi-gate FinFET, or a multi-gate planar transistor, or some other combination of devices such that the pass gate has more than one control input for the purposes described herein.

The primary control signal 202 is typically a logic signal that can control, the primary function of a pass gate. For example, during a read or write mode, the primary control signal 102 is asserted to turn on a pass gate during t1 206 to electrically connect the bit line to the bit cell during a write phase. Similarly, when the pass gate is turned on at time t3 206 by the primary control signal 202, the bit cell is electrically connected to the bit line during a read stage.

The independent control signal 204 concurrently biases the operating point of the multi-gate transistor relative to the primary control signal to provide improved operational performance. The biasing of the devices and tailoring the operating parameters during each operational phase can be based on underperforming aspects of the cell. For example, a particular bias signal may be provided to improve static noise margin during a read phase, or a different bias signal may be provided to improve cell current during the read phase if cell current is more of a concern than static noise margin. Further, during a write phase a bias voltage may be provided to improve write margin.

Thus, in a particular embodiment, after the manufacture of a device having a memory system, operational characteristics can be measured and the voltages of the independent control signal can be modified accordingly.

In a particular embodiment, independent control signal 204 provides a voltage (Vs+) that is greater than the supply voltage (Vs) of the bit cell during a write phase and time t1 206, to provide a hard turn on of a transistor in the pass gate and, therefore, improve the write margin. Alternatively, a bias voltage at or below supply voltage Vs can be provided if it is determined to provide an appropriate turn-on characteristic.

In another embodiment, during an idle or stand-by phase at time t2 208 the independent control signal 204 can provide a voltage that is at ground potential (V₀) (not shown), or between ground V₀ and the supply voltage Vs. Providing such a voltage to a gate of a multi-gate transistor of a pass gate can improve the static noise margin of the memory cell.

In yet another embodiment the independent control signal 204 provides a voltage (Vs⁻) at time t3 210 that is less than the supply voltage (Vs), but above ground during a read phase to reduce the likelihood of a destructive read.

In yet another embodiment, the independent control signal 204 provides a voltage that is at or near ground during a data retention phase to facilitate retention of data.

While the primary control signal 202 will typically toggle between two logic states, the independent signal can have many different adjustable voltage levels to bias the pass gate for improved performance. Additionally, different bias voltages can be provided to different memory cells or to different groups of memory cells during each phase of operation. The bias voltages illustrated in FIG. 2 are merely examples of possible relative voltages and timing relationships that could be provided in accordance with the present disclosure.

Referring to FIG. 3, a particular embodiment of a memory cell configuration that is traditionally referred to as a 6T configuration is illustrated. The memory cell configuration 300 is divided into functional blocks (identified by dashed lines) that include tunable pass gate TPG 302 and tunable pass gate TPG 306, both connected to bit cell 304. TPG 302, TPG 306 and bit cell 304 are functionally similar to TPG 102, TPG 106 and bit cell 104 of FIG. 1, respectively. Supply power (Vs) can be provided to the bit cell 304 via power bus 340 and supply power low (V₀), i.e., ground, can be provided via power return bus 342.

TPG 302 can be configured with a multi-gate transistor, such as a fin-type field effect transistor (FinFET) 332 having a gate 318 and a gate 320. Gate 318 can be controlled by a read/write signal that provides a logic value to control gate 332. A bias gate 318 can be controlled by a bias signal that biases transistor 332. Likewise, TPG 306 can be configured with a FinFET 334 having gate 322 and gate 324. TPG 302 can be connected to BL 314, while TPG 306 can be connected to BLB 316, wherein logic, signals can be transferred to and from the bit cell 304 and BL 314 and BLB-316 via TPG 302 and TPG 306, respectively.

In one embodiment, the memory cell configuration 300 can have four different operating phases, a read phase, a write phase, an idle phase and a retention phase. The idle phase is also referred to as a sleep phase or stand-by phase which can occur for an undefined duration when a system partially shuts down to conserve power. During an idle phase it is desirable that some subsystems such as a memory subsystem retain data but reduce power consumption. The retention phase occurs during normal operation when a read or write operation is not in process.

As illustrated, TPG 302 and TPG 306 can have control lines 308 and 310 supplied from a control module that is physically external to the memory cell 300. The control module 350 can be user configurable (i.e., programmable). Control module 350 can detect the phase of the system and provide a bias voltage responsive to the detected phase via control lines 308 and 310 to adjust the bias point of MIGFETs 332 and 334 relative to the R/W control signal received at gates 318 and 322 of TPG 302 and TPG 306, respectively.

FIG. 8 illustrates a specific embodiment of a device 800 having a control module 810 to provide bias signals. Device 800 receives control signals 801, data 802, and address 803 from a device not illustrated. Based upon the control signals 801, phase detect module 811 of control module 810 can determine a current operational phase of a memory. A signal labeled read 821 will be asserted in response to a read phase being detected. A signal labeled write 822 will be asserted in response to a write phase being detected. A signal labeled retain 823 will be asserted in response to a retention phase being detected. A signal labeled sleep 821 will be asserted in response to a sleep phase being detected. Bias select module 812 is connected to phase detect module 811 to receive an indication of a current phase of operation. Bias select module 812 can included one or more outputs. As illustrated, bias module 812 includes a plurality of outputs bias out 831, bias out 832, and bias out 833. Based upon the current phase, as indicated by an asserted signal, one or more bias output signals will be selected and provided to bias pass gates as described herein. In one embodiment, only one bias out signal is provided to all pass gates. In an alternate embodiment, each pass gate, or groups of pass gates, can be connected to receive a different bias out signal.

In the particular embodiment illustrated, the bit cell 304 stores a differential signal, and TPG 332 and TPG 334 receive the same primary control signal (R/W), however in other embodiments they can receive different control signals during operation. For example, if the read operation were single-ended and not differential, then only one of the pass gates would need to be biased for a read operation.

Changing the bias points of TPG 302 and TPG 306 can significantly improve a specific operating parameter. For example, during a write phase, increasing the forward bias of FinFET 332 and FinFET 334 with a bias signal having a voltage that is close to the supply voltage, which can include a voltage above the supply voltage, will allow FinFET 332 and FinFET 334 to be turned on hard. A hard turn on results in minimal resistance, thereby allowing current to flow with a lower forward voltage drop between bit cell 304 and BL 314 and BLB 316.

During a read phase, TPG 302 and TPG 306 can be turned on via a signal on read/write control line 326 wherein BL 314 and BLB 316 can transfer signals from the bit cell 304 to external circuits (not shown). When an improved static noise margin of memory cell 300 is desired during the read phase, control module 350, via control lines 308 and 310 can provide a voltage that is less than the supply voltage to gate 320 and gate 324. However, if increased cell current is needed for a bit cell 304 during a read mode, control module 350 can instead provide a voltage exceeding the supply voltage to gate 320 and gate 324. As stated above, the control module can provide bias voltages to gate 320 and gate 324 to change the bias point of the FinFET 332 and FinFET 334 relative to logic control signals received at gate 318 and gate 322. The bias voltage can be selected based on which operational characteristics of the bit cell 304 have the highest likelihood of causing operational failures.

It can be appreciated that it is an objective of memory cell design to provide some isolation between the storage node and the bit lines during a read operation such that the bit cell does not change states during the read cycle. However, an adequate amount of conduction must be provided by the pass gate such that a successful read process can occur. During a read phase, if noise margin is a concern, the control module 350 can provide a bias voltage, such as Vs⁻ as indicated at time t3 in FIG. 2, at the independent control lines 308 and 310 that is lower than the supply voltage. This bias voltage can cause a pass gate that turns on at less than full strength when asserted by the R/W signal. In this configuration, an impedance exists that is large enough to assist in preserving charge at the storage node during a read phase, but small enough to allow for enough current to flow such that the stored value can be read.

In the embodiment described above, altering the bias point of the FinFET 332 can assist in preserving the signal stored by the bit cell 304 and provide an improved static noise margin for the bit cell. However, if stability and static noise margin are within acceptable limits, and the bit cell is not providing an acceptable amount of cell current, a bias voltage that is near the supply voltage, which can be above the supply voltage, can be provided to allow more cell current to flow through TPG 302 and TPG 306 during the read phase. In one configuration, the bias signal can be selectively applied to individual bit cells or groups of bit cells based on the shortcomings of individual bit cells or groups of cells. For example, the voltage values of the bias signal can be determined and configured after an integrated circuit is fabricated and its characteristics understood. Thus, when it is determined what characteristics need improvement, the memory can be tuned for improved performance via the bias signals. This post fabrication feature allows manufacturers to reduce the effects of uncontrollable and unpredictable phenomena that result from fabrication variations.

During a retain phase, i.e., when a read or a write is not in process, it is beneficial for the memory cell configuration 300 to retain or hold the last written value and minimize power consumption. Hold stability is commonly qualified by the SNM in retain phase. The SNM in retain phase of a cell is the minimum DC voltage disturbance that will flip the state of the cell. During retain phase, the control module can provide a bias voltage at or near ground (proximate to ground potential) depending on the circumstances (i.e. type of bit cell and pass gate). For example, a 6T memory cell configuration may bias a pass gate at ground potential, while a 4T memory cell configuration may bias its pass gate between ground and the supply voltage to facilitate some desirable leakage current.

Many portable electronic devices have an idle mode, also referred to as a sleep mode. When a device goes into a sleep mode it is desirable to place the memory in a power conservation mode. In a sleep mode the voltage on the power bus 340 can be lowered to reduce quiescent power consumption. Thus, in a sleep mode, an independent control signal having a voltage that is near V₀ (i.e., ground) can be provided to the gates 320 and 324 to assist in preserving the stored signal. When the gates 320 and 324 are provided with a low voltage, FinFET 332 and FinFET 334 can better isolate the bit cell 304 from the bit lines 314 and 316 and any other sources of interference to reduce leakage currents.

The topology illustrated in FIG. 3 can utilize PMOS devices or NMOS devices for the memory cell 300 and could utilize numerous field effect technologies without parting from the scope of the present disclosure. Further, the configuration illustrated relates to NMOS pass gate devices, but PMOS pass gate devices could be utilized. For a PMOS configuration, the independent control signals can be referenced around the ground potential instead of Vs as described. To improve the performance of a PMOS pass gate during a read or a write phase, the independent control signal can provide a voltage that is below ground to strengthen the PMOS pass gate response to R/W signal, while the independent control signal can be above ground to provide a weaker PMOS pass gate during the read phase. During the idle and retention phases, the independent control signal can be at or near Vs or between Vs and V₀ to address any shortcomings of the system during these phases.

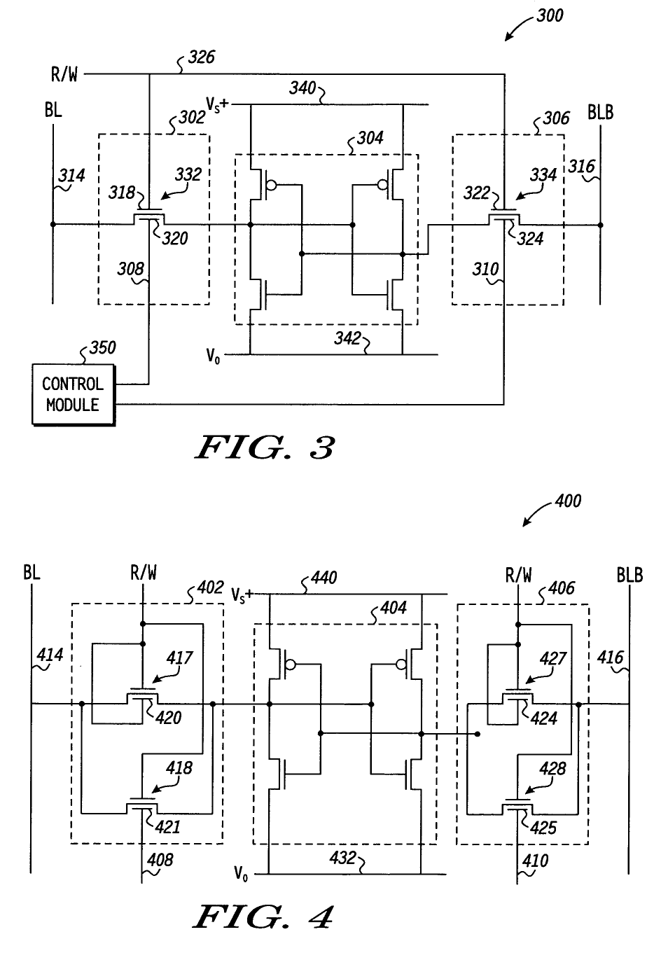

Referring to FIG. 4 another 6T memory cell configuration is illustrated. The memory cell configuration 400 is again divided into functional blocks (separated by dashed lines) that include tunable pass gate TPG 402 and tunable pass gate TPG 406 both connected to a bit cell 404. TPG 402, TPG 406 and bit cell 404 are functionally similar to TPG 102, TPG 106 and bit cell 104 of FIG. 1, respectively. Power (Vs) can be provided to the bit cell 404 via power bus 440 and V₀, possibly at ground potential, can be provided via power return bus 432. Although the illustrated configuration has eight transistors, the pass gate or hybrid switch can be considered as a single transistor and the configuration will follow the general operational principals of a 6T configuration.

TPG 402 can be connected to BL 414, while TPG 406 can be connected to BLB 416 such that logic signals can be transferred to and from the bit cell 404. In the embodiment depicted, a hybrid switch configuration is utilized for TPG 402 and TPG 406. The hybrid switch can be created by connecting current electrodes of MIGFET 417 in parallel with the current electrodes of multi-gate transistor 418, connecting gates 421 and 425 to a control module (not shown) to receive a bias signal, and all other gates of transistors 417 and 418 to receive the R/W signal. TPG 406 is configured in a similar manner with gate 425 connected to receive the bias signal, and gates 424, 427, and 428 connected to the R/W signal. In this configuration TPG 402 and TPG 406 provide finer bias control relative to the logic signal R/W because the total gate area controlled by the bias signal is less than in the embodiment described previously using a single multi-gate transistor.

Referring to FIG. 5, another exemplary embodiment of a memory cell configuration 500 is illustrated. The memory cell configuration 500 is divided into functional blocks (separated by dashed lines) that include tunable pass gate TPG 502, tunable pass gate TPG 506 and a bit cell 504 that are that are functionally similar to TPG 102, TPG 106 and bit cell 104 of FIG. 1, respectively. The illustrated configuration is often referred to as a 4T memory cell configuration because the traditional cell configuration utilizes 4 transistors. Although the illustrated configuration has six transistors, the pass gate or hybrid switch can be considered as a single transistor and the configuration will follow the general operational principals of a 4T configuration.

TPG 502 can be connected to BL 514, while TPG 506 can be connected to BLB 516 such that logic signals can be transferred to and from the bit cell 504. In the embodiment depicted, a hybrid switch similar to that described at FIG. 3 is utilized in both TPG 502 and TPG 506.

A 4T memory cell configuration requires less chip area than a 6T-configuration, but 4T memory cells consume more power, are less efficient and have other shortcomings. Namely, a traditional 4T configuration has greater stability issues and consumes considerable stand-by power then a 6T configuration because high quiescent currents are utilized to ensure cell stability. Shortcomings of a 4T cell configuration can be improved by tuning the operational characteristics of TPG 502 and TPG 506. For example, the hybrid switches of TPG 502 and TPG 506 can be biased to provide improved performance for a 4T cell configuration by introducing a greater range of impedance values.

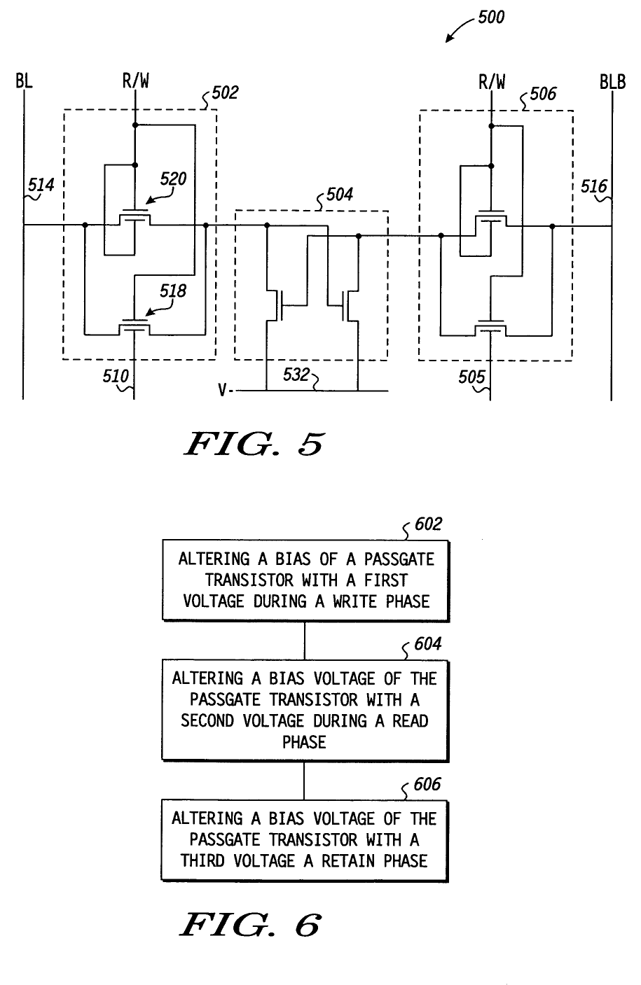

FIG. 6 is a flow diagram depicting a method for biasing a memory cell during different memory system phases. As illustrated by block 602, a bias point of a transistor within a pass gate is altered with a first voltage during a write phase. The bias point can be altered by supplying a voltage to a gate of a multi-gate transistor of the pass gate. At block 604, a second voltage is provided to the pass gate during a read phase to alter the bias voltage of the MIGFET. At block 606, a third bias voltage is provided to the MIGFET transistor in the pass gate during a sleep mode or a retain phase. Thus, depending on the current phase of the memory cell a bias signal having different voltage levels can be provided to the pass gate. The actual bias signal voltage that is utilized in each of the phases can be tailored to improve a performance characteristic of the memory cell during that phase.

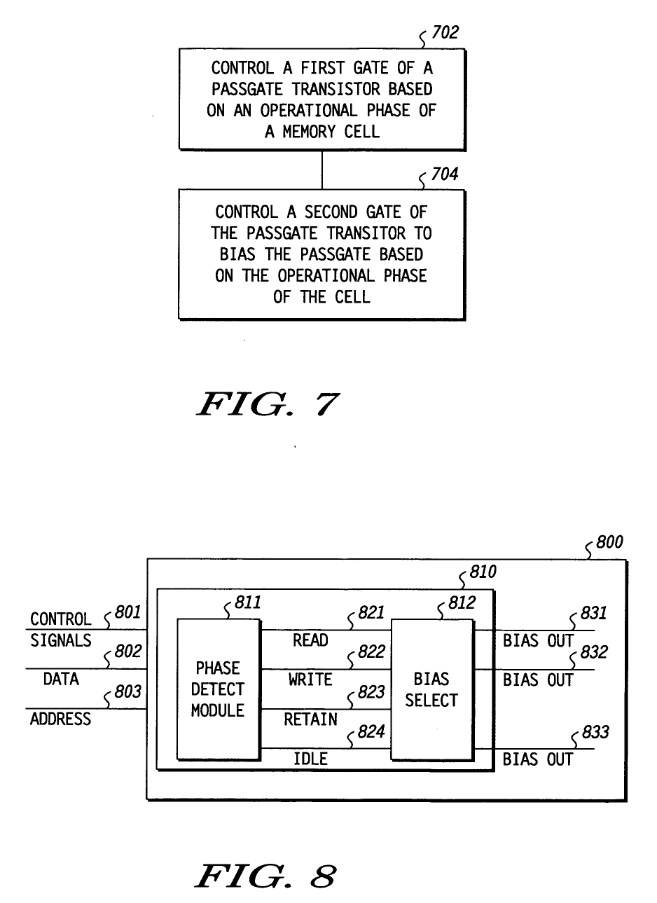

Referring to FIG. 7 another method of controlling a memory cell is provided. As illustrated in block 702, a first gate of a multi-gate transistor is controlled by a read/write control signal. The read/write control signal is based upon the operational phase of the memory system. For example, R/W signal is asserted when a memory is preferring a read or write operation, and negated during a retention or sleep operation.

As illustrated in block 704 a second gate of the multi-gate transistor is provided with a control signal. The control signal can be a voltage wherein the voltage can alter a bias of the multi-gate transistor. Different bias voltages can be provided during each of the phases of memory cell operation. The voltage of the control signal can be tailored to tune the performance parameters of the access transistors based on the operational improvements that can be achieved.

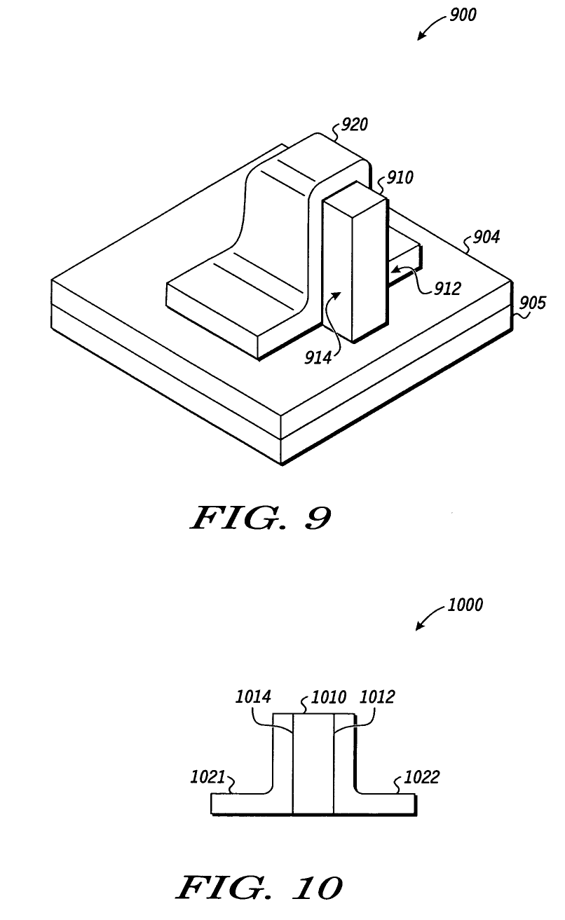

FIG. 9 illustrates, in 3-dimensional perspective, a specific type of FinFET formed at a substrate that includes an insulative layer 904 and support layer 905 that can be used in accordance with the present disclosure. The transistor of FIG. 9 is a single gate FinFET, comprising a signal conductive gate 920 formed overlying a semiconductor fin structure 910. Note that a gate dielectric (not shown) is typically formed between conductive gate 920 and semiconductor fin structure 910. The semiconductor fin structure 910 comprises a first surface 912 and a second surface 914. Surfaces 912 and 914 are opposing surfaces, and represent planar surfaces at which channel regions are formed underlying conductive gate 920. It will be appreciated, that while a first channel region can be formed near surface 912 under conductive gate 920, and a second channel region can be formed near surface 914 under conductive gate 920, that in effect, based upon the thickness of the semiconductor fin structure 910, that a channel region can be formed through the entire thickness of fin structure 910 between surfaces 912 and 914 under conductive gate 920.

FIG. 10 illustrates a cross-sectional view of a multi-gate FinFET 1000. The multi-gate FinFET 1000 differs from the single gate FinFET of 900 of FIG. 9 in that there are separate conductive control gates 1021 and 1022 that are used to control different channel regions of the semiconductor fin structure 1010. It will be appreciated that a first channel region near the surface 1012 of semiconductor fin structure 1010, that underlies conductive gate structure 1022, will be substantially controlled by conductive gate structure 1022. Similarly, a second channel region near the surface 1014 of semiconductor fin structure 1010, that underlies gate structure 1021, will be substantially controlled by the conductive gate 1021. In this manner, a signal provided to one of the conductive gates, such as conductive gate 1022, can act to bias the overall FinFET 1000, such that the response of the FinFET 1000 to a control signal at conductive gate 1021 is affected. For example, assuming conductive gate 1022 is biased by a high voltage level, the effect of a low to high transitioning signal on conductive gate 1021 results in turning the FinFET 1000 fully on more rapidly than if conductive gate 1022 were biased by a low voltage level. When turned on, carriers in the channel regions flow in a direction substantially parallel to a primary surface of the substrate.

It will be appreciated that future memory cell configurations or future circuits with similar design challenges or issues can use the techniques herein. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. Accordingly, the present disclosure is not intended to be limited to the specific form set forth herein, but on the contrary, it is intended to cover such alternatives, modifications, and equivalents, as can be reasonably included within the spirit and scope of the disclosure.

1. A system comprising:
a bit cell comprising a first node configured to store a signal representing a state of the bit cell; and
a multi-gate transistor comprising a first electrode coupled to the first node of the bit cell, a second electrode coupled to a bit line, a first gate electrode coupled to a read/write line, and a second gate electrode configured to receive a bias signal.

2. The system as in claim 1, further comprising a control module comprising an output coupled to the second gate electrode of the multi-gate transistor provide the bias signal.

3. The system as in claim 2, wherein the control module provides the bias signal having a first voltage during a retention phase.

4. The system of claim 1, wherein the control module comprises a phase detect module to determine an operating phase of the bit cell and a bias select module to select a voltage for the bias signal based upon the operating phase.

5. The system as in claim 4, wherein the voltage selected by the select module is user configurable.

6. The system as in claim 4, wherein the voltage selected by the select module is less than a voltage at a supply node when a write phase is detected by the phase detect module.

7. The system as in claim 4, wherein the voltage selected by the select module is greater than a voltage at a supply node when a write phase is detected by the phase detect module.

8. The system as in claim 4, wherein the voltage selected by the select module is less than a voltage at a supply node when a read phase is detected by the phase detect module.

9. The system as in claim 1 wherein the multi-gate transistor comprises a fin-type field effect transistor (FinFET).

10. The system as in claim 1, wherein the independent control line is manufactured parallel with the bit line.

11. A method comprising:
receiving a read/write control signal to control a first gate of a multi-gate transistor of a bit cell; and
receiving a bias signal to control a second gate of the multi-gate transistor wherein the bias signal alters a bias point of the multi-gate transistor.

12. The method of claim 11 wherein the bias signal alters a bias point of the multi-gate transistor based upon an operational phase of the bit cell.

13. The method of claim 11, wherein the bias signal has a voltage lower than a supply voltage of the bit cell during a retention phase.

14. The method of claim 13, wherein the bias signal has a voltage approximately equal to ground.

15. The method of claim 11, wherein the bias signal has a voltage that is less than a supply voltage during a read phase.

16. The method of claim 15, wherein the bias signal has a voltage that is greater than the bias signal during the read phase.

17. A digital data storage system comprising:
a bit cell;
a multi-gate field effect transistor comprising a first current electrode coupled to a bit line, a second current electrode coupled to the bit cell, a first gate coupled to a read/write control line and a second gate; and
a control module comprising an output coupled to the second gate of the multi-gate field effect transistor to bias the multi-gate field effect transistor.

18. The digital data storage system as in claim 17 wherein the multi-gate field affect transistor comprises a fin-type field effect transistor (FinFET).

19. The digital data storage system as in claim 17 wherein the control module selects a voltage to be provided to the second gate to alter an impedance of the multi-gate field effect transistor based upon an operational phase of the digital storage system.

20. The digital data storage system as in claim 19 wherein the voltage selected by the control module is user configurable.
